(19) United States
(12) Patent Application Publication
(10) Pub. No.: US 2025/0142854 A1
(43) Pub. Date: May 1, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Rudy Octavius Sihombing, Batam (ID); Su Xing, Singapore (SG)

(73) Assignee: UNITED MICROELECTRONICS CORP., Hsin-Chu City (TW)

(21) Appl. No.: 18/523,930

(22) Filed: Nov. 30, 2023

(30) Foreign Application Priority Data
Oct. 30, 2023 (TW) 112141472

(51) Int. Cl. H01L 29/66; H01L 29/78

(52) U.S. Cl. CPC H10D 30/0229; H10D 30/605

(57) ABSTRACT

A method for fabricating semiconductor device includes the steps of first providing a substrate having a high-voltage (HV) region and a low-voltage (LV) region, forming a first gate structure on the HV region and a second gate structure on the LV region, forming a first lightly doped drain (LDD) adjacent to one side of the first gate structure and a second LDD adjacent to another side of the first gate structure, and then forming a third lightly doped drain (LDD) adjacent to one side of the second gate structure and a fourth LDD adjacent to another side of the second gate structure. Preferably, the first LDD and the second LDD are asymmetrical, the third LDD and the fourth LDD are asymmetrical, and the second LDD and the third LDD are symmetrical.

### BACKGROUND OF THE INVENTION

### 1. Field of the Invention

The invention relates to a semiconductor device and fabrication method thereof, and more particularly, to a radio frequency (RF) device and fabrication method thereof.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

Typically, current RF devices often have drawbacks including higher resistance and large parasitic capacitance that ultimately affect overall performance of the devices. Hence, how to improve current RF device structures for resolving this issue has become an important task in this field.

### SUMMARY OF THE INVENTION

According to an embodiment of the present invention, a method for fabricating semiconductor device includes the steps of first providing a substrate having a high-voltage (HV) region and a low-voltage (LV) region, forming a first gate structure on the HV region and a second gate structure on the LV region, forming a first lightly doped drain (LDD) adjacent to one side of the first gate structure and a second LDD adjacent to another side of the first gate structure, and then forming a third lightly doped drain (LDD) adjacent to one side of the second gate structure and a fourth LDD adjacent to another side of the second gate structure. Preferably, the first LDD and the second LDD are asymmetrical, the third LDD and the fourth LDD are asymmetrical, and the second LDD and the third LDD are symmetrical.

According to another aspect of the present invention, a semiconductor device includes a substrate having a high-voltage (HV) region and a low-voltage (LV) region, a first gate structure on the HV region and a second gate structure on the LV region, a first lightly doped drain (LDD) adjacent to one side of the first gate structure and a second LDD adjacent to another side of the first gate structure, and a third lightly doped drain (LDD) adjacent to one side of the second gate structure and a fourth LDD adjacent to another side of the second gate structure. Preferably, the first LDD and the second LDD are asymmetrical, the third LDD and the fourth LDD are asymmetrical, and the second LDD and the third LDD are symmetrical.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a top view layout of a RF device according to an embodiment of the present invention.

FIGS. 2-6 illustrate a method for fabricating the RF device along the sectional line AA′ of FIG. 1 according to an embodiment of the present invention.

FIGS. 7-8 illustrate a method for fabricating a RF device according to an embodiment of the present invention.

FIG. 9 illustrates a comparison of concentration distribution of LDDs extending along X and Y directions between embodiments shown in FIGS. 6 and 8.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

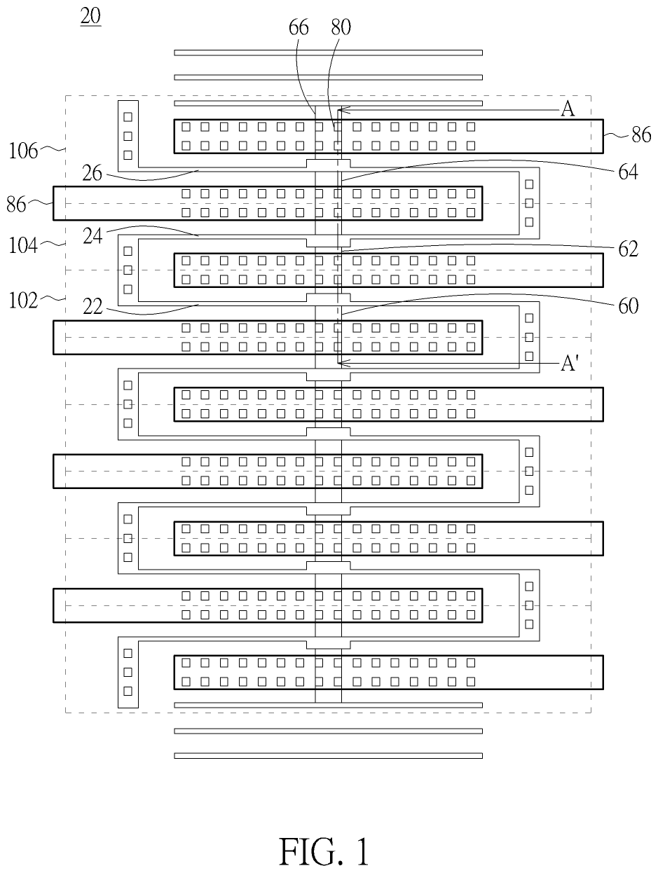

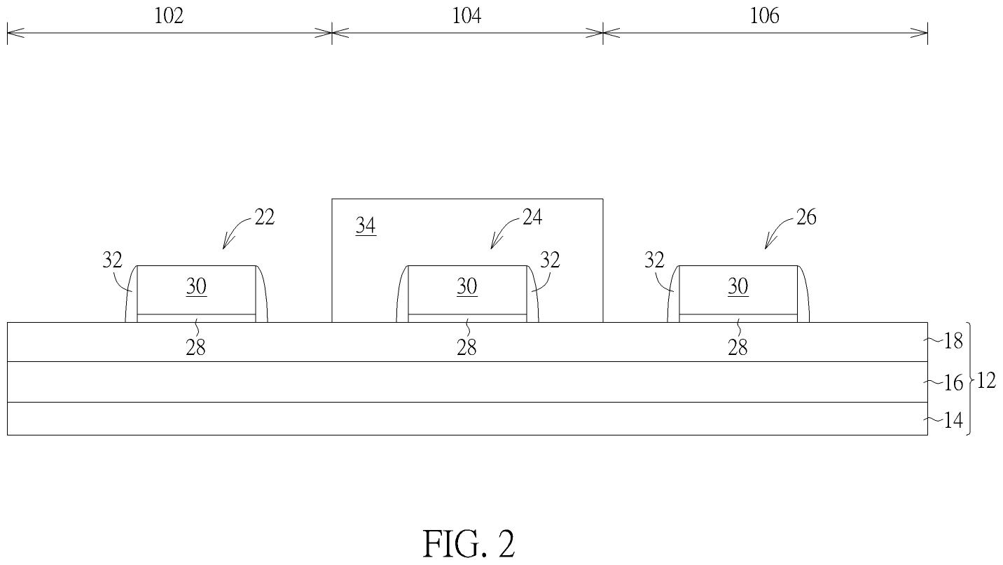

Referring to FIGS. 1-6, FIG. 1 illustrates a top view layout of a RF device or more specifically a power amplifier according to an embodiment of the present invention and FIGS. 2-6 illustrate a method for fabricating the RF device along the sectional line AA′ of FIG. 1 according to an embodiment of the present invention. As shown in FIGS. 1-2, a substrate 12 made of semiconductor material is provided and a plurality of high-voltage (HV) cells or HV regions and a plurality of low-voltage (LV) cells or LV regions extending along the X-direction are defined on the substrate 12, in which the HV regions and the LV regions are disposed alternately immediately adjacent to each other such that the regions immediately adjacent to two sides of the HV regions are LV regions and regions immediately adjacent to two sides of the LV regions are HV regions. For simplicity purpose, only two HV regions 102, 106 and a LV region 104 between the HV regions 102, 106 are labeled in FIG. 1. Moreover, the number of the HV regions and LV regions are not limited to the ones shown in FIG. 1, but could all be adjusted according to the demand of the product.

In this embodiment, the substrate 12 preferably includes a silicon-on-insulator (SOI) substrate, which further includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto.

It should be noted that even though the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, part of the second semiconductor layer 18 could be removed to fill an insulating material for forming a shallow trench isolation (STI) 20 around the HV regions and LV regions and a transistor device in the RF device could be fabricated on the second semiconductor layer 18 surrounded by the STI 20 in the later process.

Next, gates structures 22, 24, 26 or dummy gates are formed on the substrate 12. In this embodiment, the formation of the gate structures 22, 24, 26 could be accomplished by a gate first process, a high-k first approach from gate last process, or a high-k last approach from gate last process. Since this embodiment pertains to a high-k last approach, a gate dielectric layer 28 or interfacial layer made of silicon oxide, a gate material layer 30 made of polysilicon, and a selective hard mask (not shown) could be formed sequentially on the substrate 12, and a photo-etching process is then conducted by using a patterned resist (not shown) as mask to remove part of the gate material layer 30 and part of the gate dielectric layer 28 through single or multiple etching processes. After stripping the patterned resist, gate structures 22, 24, 26 each composed of a patterned gate dielectric layer 28 and a patterned material layer 30 are formed on the substrate 12.

Next, a spacer such as an offset spacer 32 is formed on sidewalls of each of the gate structures 22, 24, 26, and then a patterned mask 34 such as patterned resist is formed to cover all of the HV regions 102, 106 or all of the LV regions 104. For instance, in this embodiment, the patterned mask 34 is formed to cover the gate structure 24 and substrate 12 surface on the LV region 104 and expose the gate structures 22, 26 and substrate 12 surface on the adjacent HV regions 102, 106.

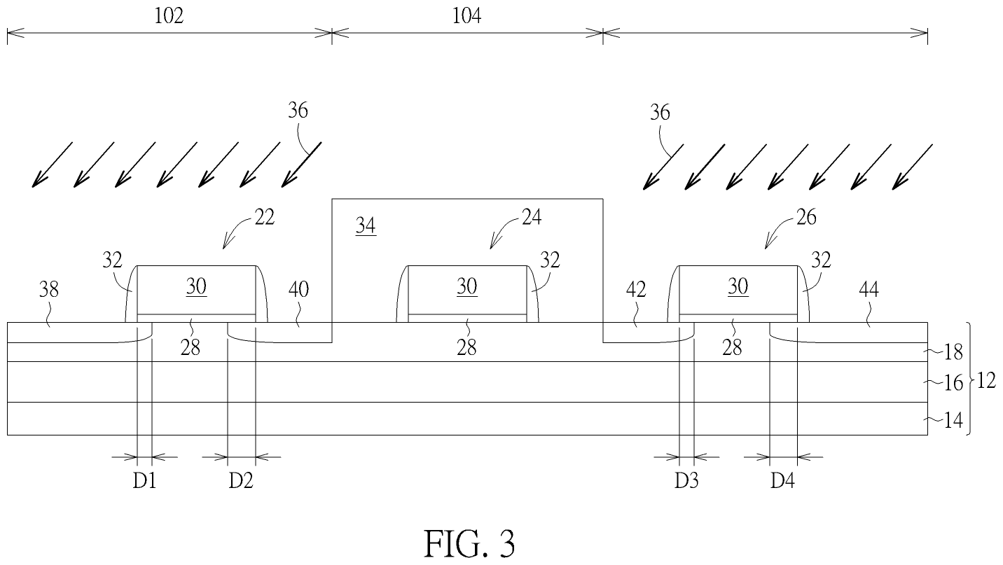

Next, as shown in FIG. 3, an ion implantation process 36 is conducted to implant n-type or p-type dopants into the substrate 12 adjacent to two sides of the offset spacers 32 on the HV regions 102, 106 and a selective anneal process could also be conducted thereafter to form lightly doped drains (LDDs) 38, 40 adjacent to two sides of the gate structure 22 and LDDs 42, 44 adjacent to two sides of the gate structure 26. It should be noted that ion implantation process 36 conducted at this stage pertains to be a tilt angle ion implantation process, which preferably implants dopants into the substrate 12 adjacent to the gate structures 22, 26 on the HV regions 102, 106 at an angle less than 90 degrees or most preferably less than 80 degree, 70 degrees, 60 degrees, or even at 45 degrees. Since the ion implantation process 36 is conducted at a tilt angle, the LDDs 38, 40, 42, 44 formed adjacent to two sides of the gate structures 22, 26 therefore become asymmetric structures. For instance, the LDD 38 adjacent to left side of the gate structure 22 and the LDD 40 adjacent to right side of the gate structure 22 are asymmetrical and the LDD 42 adjacent to left side of the gate structure 26 and the LDD 44 adjacent to right side of the gate structure 26 are also asymmetrical.

In this embodiment, aforementioned asymmetry or asymmetric structures could be referred to as a distance of the LDD extending inward along horizontal or X-direction to the region directly under the gate structures 22, 24, 26 adjacent to one side of the gate structures 22, 24, 26 to be different from another distance of the LDD extending inward along horizontal or X-direction to the region directly under the gate structures 22, 24, 26 adjacent to another side of the gate structures 22, 24, 26, in which the distance of the LDD extending inward along horizontal or X-direction could begin from outer sidewall of the spacers 32 or sidewalls of the gate structures 22, 24, 26, which are all within the scope of the present invention. Moreover, a deepest distance of the LDD extending downward along vertical or Y-direction till reaching the insulating layer 16 adjacent to one side of the gate structures 22, 24, 26 could also be different from another deepest distance of the LDD extending downward along vertical or Y-direction till reaching the insulating layer 16 adjacent to another side of the gate structures 22, 24, 26.

Taking the LDDs 38, 40, 42, 44 formed on the HV regions 102, 106 as an example, a distance D1 of the LDD 38 extending along horizontal or X-direction adjacent to left side of the gate structure 22 is less than a distance D2 of the LDD 40 extending along horizontal or X-direction adjacent to right side of the gate structure 22. Nevertheless, the deepest distance of the LDD 38 extending along vertical or Y-direction adjacent to left side of the gate structure 22 is substantially equal to the deepest distance of the LDD 40 extending along vertical or Y-direction adjacent to right side of the gate structure 22.

Similarly, a distance D3 of the LDD 42 extending along horizontal or X-direction adjacent to left side of the gate structure 26 is less than a distance D4 of the LDD 44 extending along horizontal or X-direction adjacent to right side of the gate structure 26. Nevertheless, the deepest distance of the LDD 42 extending along vertical or Y-direction adjacent to left side of the gate structure 26 is substantially equal to the deepest distance of the LDD 44 extending along vertical or Y-direction adjacent to right side of the gate structure 26. Overall, distance D1=D3 and D2=D4.

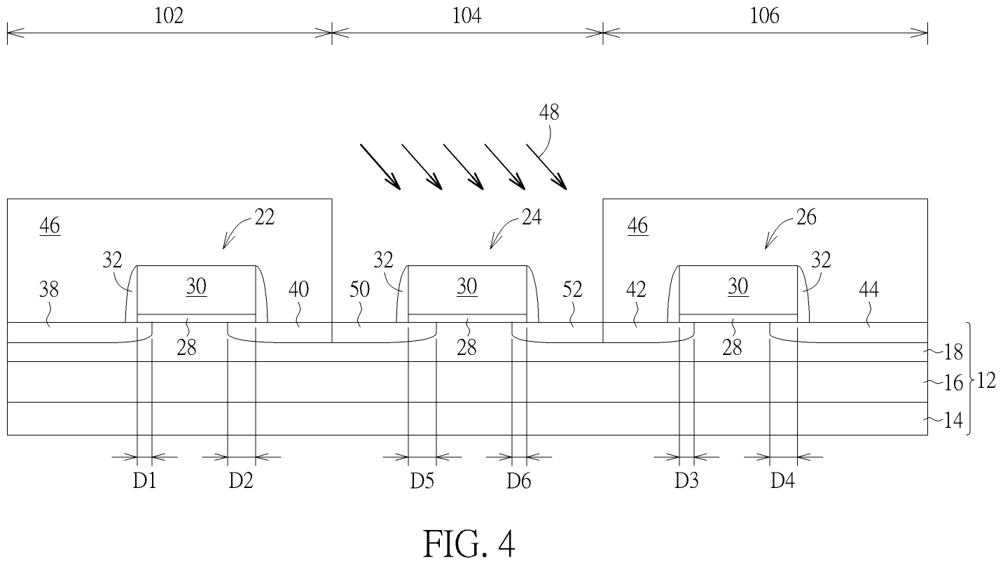

As shown in FIG. 4, the patterned mask 34 is removed and another patterned mask 46 such as patterned resist is formed to cover the gate structures 22, 26 and substrate 12 surface of the HV regions 102, 106 and expose the gate structure 24 and substrate 12 surface of the LV region 104, the substrate 12 or silicon wafer is rotated 180 degrees, and then an ion implantation process 48 is conducted to implant n-type or p-type dopants into the substrate 12 adjacent to two sides of the offset spacers 32 on the LV region 104 accompanied by an optional anneal process for forming LDDs 50, 52 adjacent to two sides of the gate structure 24. It should be noted that even though this embodiment forms the patterned mask 46 and then rotates the substrate 12 afterwards, according to other embodiment of the present invention, it would also be desirable to first rotate the substrate 12 after removing the patterned mask 34, and then form the patterned mask 46 afterwards, which is also within the scope of the present invention.

Similar to the aforementioned ion implantation process 36, the ion implantation process 48 conducted at this stage includes a tilt angle ion implantation process, which implants dopants into the substrate 12 adjacent to the gate structure 24 on the LV regions 104 at an angle less than 90 degrees or most preferably less than 80 degree, 70 degrees, 60 degrees, or even at 45 degrees. Since the ion implantation process 36 is conducted at a tilt angle, the LDDs 50, 52 formed adjacent to two sides of the gate structure 24 preferably become asymmetric structures. For instance, the LDD 50 adjacent to left side of the gate structure 24 and the LDD 52 adjacent to right side of the gate structure 24 are asymmetrical. In this embodiment, the ion implantation processes 36, 48 are conducted at different directions, same angle, and under same dopant concentrations, hence the LDDs 38, 40, 42, 44, 50, 52 preferably have same concentration and same depths.

Specifically, a distance D5 of the LDD 50 extending along horizontal or X-direction adjacent to left side of the gate structure 24 is greater than a distance D6 of the LDD 52 extending along horizontal or X-direction adjacent to right side of the gate structure 24. Nevertheless, the deepest distance of the LDD 50 extending along vertical or Y-direction adjacent to left side of the gate structure 24 is substantially equal to the deepest distance of the LDD 52 extending along vertical or Y-direction adjacent to right side of the gate structure 24. Overall, distance D1=D3=D6 and D2=D4=D5.

It should be noted that the angle of the ion implantation process 48 conducted at this stage is preferably the same as the angle of the ion implantation process 36 conducted on the HV regions 102, 106 on FIG. 3. However, since this stage first rotates the substrate 12 180 degrees and then conducts the tilt angle ion implantation process 48 on the LV region 104, the ion implantation process 36 and the ion implantation process 48 then become opposite direction as the LDDs 50, 52 adjacent to two sides of the gate structure 24 on the LV region 104 now become a mirror image structure of the LDDs 38, 40 adjacent to two sides of the gate structure 22 on the HV region 102 or mirror image structure of the LDDs 42, 44 adjacent two sides of the gate structure 26 on the HV region 106.

In other words, the LDD 50 adjacent to left side of the gate structure 24 on the LV region 104, the LDD 40 adjacent to right side of the gate structure 22 on the HV region 102, and the LDD 44 adjacent to right side of the gate structure 26 on the HV region 106 are symmetric structures, and the LDD 52 adjacent to right side of the gate structure 24 on the LV region 104, the LDD 38 adjacent to left side of the gate structure 22 on the HV region 102, and the LDD 42 adjacent to left side of the gate structure 26 on the HV region 106 are symmetric structures.

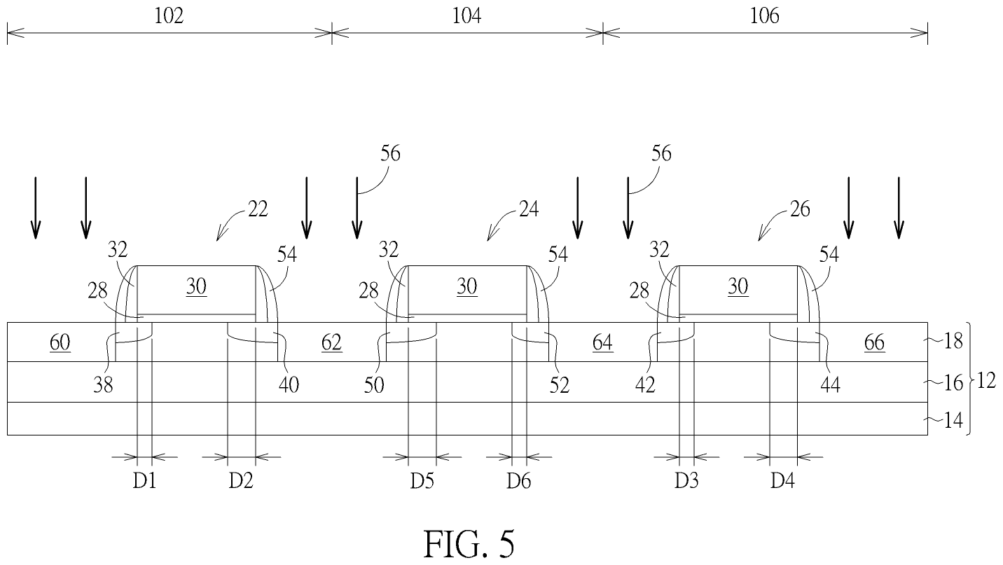

Next, as shown in FIG. 5, after removing the patterned mask 46, another spacer or main spacer 54 is formed adjacent to the offset spacers 32 on the HV regions 102, 106 and the LV region 104, an ion implantation process 56 is conducted to implant n-type or p-type dopants into the substrate 12 adjacent to two sides of the substrate 12 for forming source/drain regions 60, 62, 64, 66, and epitaxial layers (not shown) and/or silicides (not shown) could be formed selectively adjacent to two sides of the main spacers 54. It should be noted that in contrast to the ion implantation processes 36, 48 conducted for forming the LDDs 38, 40, 42, 44, 50, 52 are tilt angle ion implantation processes, the ion implantation process 56 conducted to form the source/drain regions 60, 62, 64, 66 is a right angle ion implantation process. Hence the source/drain regions 60, 62, 64, 66 adjacent to two sides of the gate structures 22, 24, 26 are symmetric structures. Moreover, the source/drain regions 60, 64 are preferably drain regions while the source/drain regions 62, 66 are source regions.

In this embodiment, the offset spacers 32 and the main spacers 54 could include same material or different material while both the offset spacers 32 and the main spacers 54 could be made of material including but not limited to for example SiO₂, SiN, SiON, SiCN, or combination thereof. The source/drain regions 60, 62, 64, 66 and the epitaxial layer could include different dopants or different materials depending on the type of device being fabricated. For instance, the source/drain regions 60, 62, 64, 66 could include n-type dopants or p-type dopants and the epitaxial layers could include silicon germanium (SiGe), silicon carbide (SiC), or silicon phosphide (SiP).

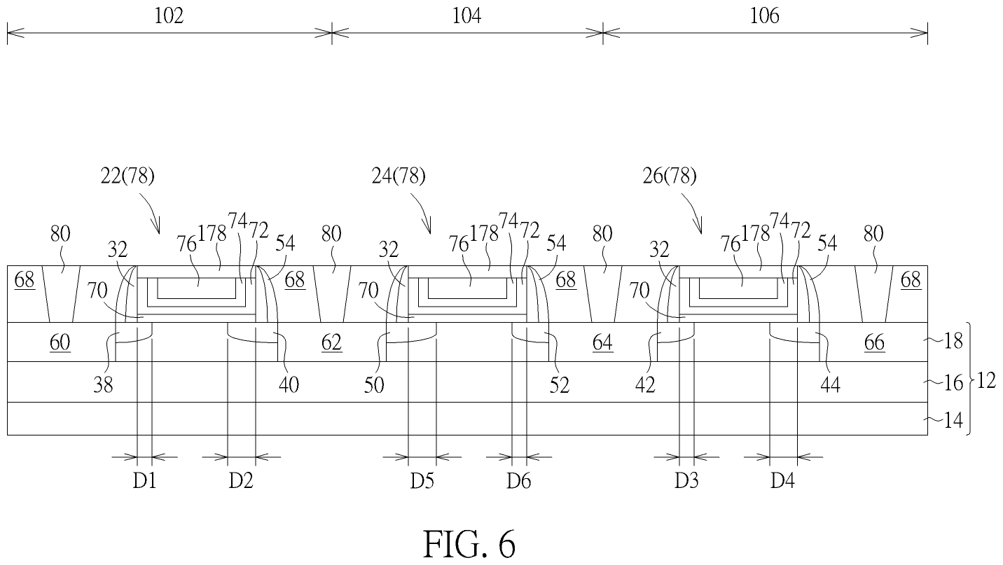

Next, as shown in FIG. 6, a selective contact etch stop layer (CESL) and an interlayer dielectric (ILD) layer 68 are formed on the gate structures 22, 24, 26 and a planarizing process such as chemical mechanical polishing (CMP) process is conducted to remove part of the ILD layer 68 for exposing the gate material layers 30 made of polysilicon so that the top surface of the gate material layers 30 is even with the top surface of the ILD layer 68.

Next, a replacement metal gate (RMG) process is conducted to transform the gate structures 22, 24, 26 into metal gates 78. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layers 30 and even the gate dielectric layers 28 for forming recesses in the ILD layer 68.

Next, a selective interfacial layer 70 or gate dielectric layer, a high-k dielectric layer 72, a work function metal layer 74, and a low resistance metal layer 76 are formed in the recesses, and a planarizing process such as CMP is conducted to remove part of low resistance metal layer 76, part of work function metal layer 74, and part of high-k dielectric layer 72 for forming metal gates 78. In this embodiment, the gate structures or metal gates 78 fabricated through high-k last process of a gate last process preferably includes an interfacial layer or gate dielectric layer, a U-shaped high-k dielectric layer 72, a U-shaped work function metal layer 74, and a low resistance metal layer 76.

In this embodiment, the high-k dielectric layer 72 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 74 is formed for tuning the work function of the metal gate in accordance with the conductivity of the device. For an NMOS transistor, the work function metal layer 74 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 74 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 74 and the low resistance metal layer 76, in which the material of the barrier layer may include titanium (Ti), titanium nitride (TiN), tantalum (Ta) or tantalum nitride (TaN). Furthermore, the material of the low-resistance metal layer 76 may include copper (Cu), aluminum (Al), titanium aluminum (TiAl), cobalt tungsten phosphide (CoWP) or any combination thereof.

Next, part of the high-k dielectric layer 72, part of the work function metal layer 74, and part of the low resistance metal layer 76 are removed to form recesses (not shown), and a hard mask 178 is formed into each of the recesses so that the top surfaces of the hard masks 178 and the ILD layer 68 are coplanar. Preferably the hard masks 178 could include SiO₂, SiN, SiON, SiCN, or combination thereof.

Next, a photo-etching process is conducted by using a patterned mask (not shown) as mask to remove part of the ILD layer 68 adjacent to the gate structure 22, 24, 26 for forming contact holes (not shown) exposing the source/drain regions 60, 62, 64, 66. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and metal layer for forming contact plugs 80 electrically connecting the source/drain regions 60, 62, 64, 66. It should be noted that two contact holes 80 are disposed adjacent to two sides of each of the gate structures 22, 24, 26 as shown in FIG. 1, only a single contact plug 80 disposed adjacent to two sides of the gate structures 22, 24, 26 are shown in the cross-section views of this embodiment for simplicity purpose. Lastly, metal interconnect process including forming inter-metal dielectric (IMD) layers on top of the ILD layer 68 and metal interconnections 86 in the IMD layers as shown in FIG. 1 for passing signals from the contact plugs 80 to external devices. This completes the fabrication of a RF device according to an embodiment of the present invention.

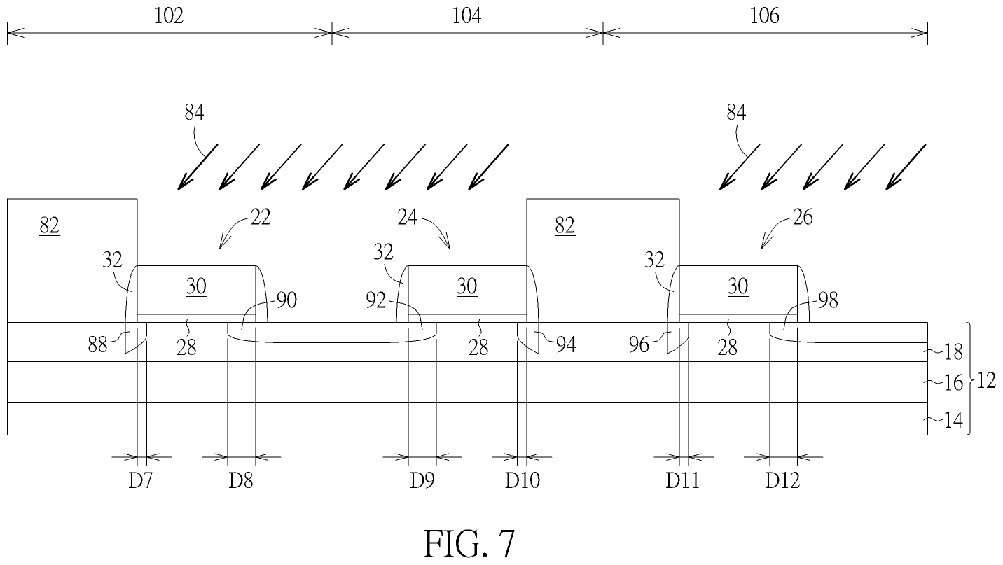

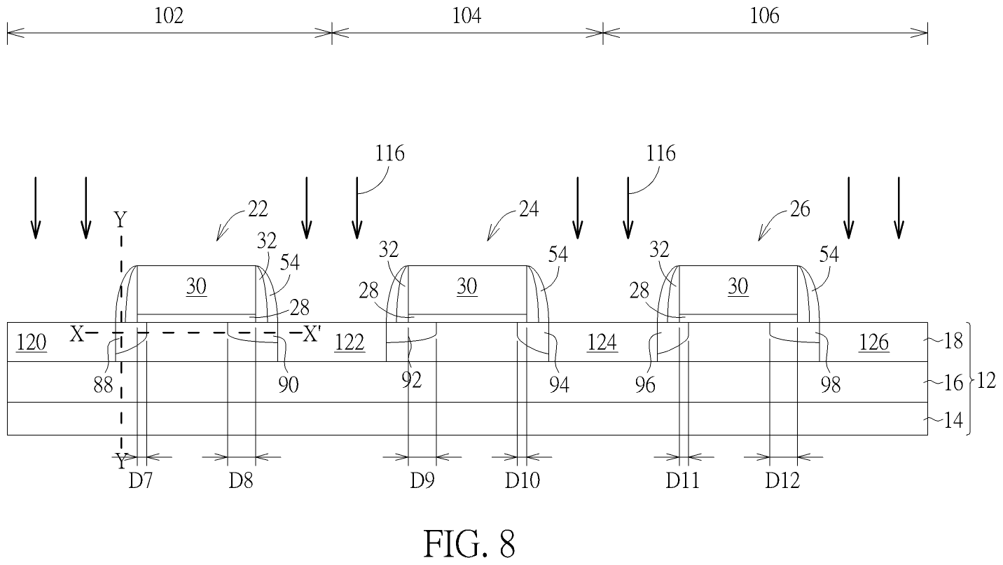

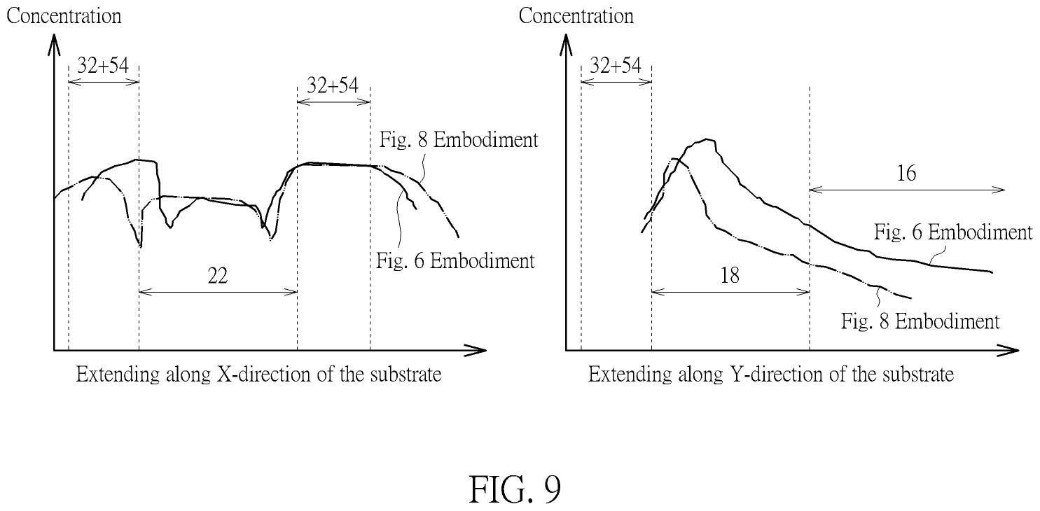

Referring to FIGS. 7-9, FIGS. 7-8 illustrate a method for fabricating a RF device according to an embodiment of the present invention and FIG. 9 illustrates a comparison of concentration distribution of LDDs extending along X and Y directions between embodiments shown in FIGS. 6 and 8. As shown in FIG. 7, it would be desirable to follow the aforementioned embodiment by forming gate structures 22, 24, 26 or dummy gates on the substrate 12 and offset spacers 32 on sidewalls of the gate structures 22, 24, 26 and then forming a patterned mask 82 such as a patterned resist on drain regions that will be formed afterwards adjacent to one side of the gate structures 22, 24, 26. For instance, the patterned mask 82 is formed on the substrate 12 surface and offset spacers 32 adjacent to left side of the gate structure 22 and between the gate structures 24, 26.

Next, an ion implantation process 84 is conducted to implant n-type or p-type dopants into the substrate 12 adjacent to two sides of the offset spacer 32 on the HV region 102, LV region 104, and HV region 106 along with an optional anneal process for forming LDDs 88, 90, 92, 94, 96, 98 adjacent to two sides of the gate structures 22, 24, 26.

Similar to the aforementioned ion implantation processes 36, 48, the ion implantation process 84 conducted at this stage includes a tilt angle ion implantation process, which implants dopants into the substrate 12 adjacent to two sides of the gate structures 22, 24, 26 on the HV region 102, LV region 104, and HV region 106 at an angle less than 90 degrees or most preferably less than 80 degree, 70 degrees, 60 degrees, or even at 45 degrees. Since the ion implantation process 84 is conducted at a tilt angle, the LDDs 88, 90, 92, 94, 96, 98 formed adjacent to two sides of the gate structures 22, 24, 26 preferably become asymmetric structures. For instance, the LDD 88 adjacent to left side of the gate structure 22 and the LDD 90 adjacent to right side of the gate structure 22 are asymmetrical, the LDD 92 adjacent to left side of the gate structure 24 and the LDD 94 adjacent to right side of the gate structure 24 are asymmetrical, and the LDD 96 adjacent to left side of the gate structure 26 and the LDD 98 adjacent to right side of the gate structure 26 are asymmetrical.

In this embodiment, a distance D7 of the LDD 88 extending along horizontal or X-direction adjacent to left side of the gate structure 22 is less than a distance D8 of the LDD 90 extending along horizontal or X-direction adjacent to right side of the gate structure 22, and the deepest distance of the LDD 88 extending downward along vertical or Y-direction adjacent to left side of the gate structure 22 is substantially greater than the deepest distance of the LDD 90 extending downward along vertical or Y-direction adjacent to right side of the gate structure 22.

Similarly, a distance D9 of the LDD 92 extending along horizontal or X-direction adjacent to left side of the gate structure 24 is greater than a distance D10 of the LDD 94 extending along horizontal or X-direction adjacent to right side of the gate structure 24, and the deepest distance of the LDD 92 extending downward along vertical or Y-direction adjacent to left side of the gate structure 24 is substantially less than the deepest distance of the LDD 94 extending downward along vertical or Y-direction adjacent to right side of the gate structure 24.

Lastly, a distance D11 of the LDD 96 extending along horizontal or X-direction adjacent to left side of the gate structure 26 is less than a distance D12 of the LDD 98 extending along horizontal or X-direction adjacent to right side of the gate structure 26, and the deepest distance of the LDD 96 extending downward along vertical or Y-direction adjacent to left side of the gate structure 26 is substantially greater than the deepest distance of the LDD 98 extending downward along vertical or Y-direction adjacent to right side of the gate structure 26. Overall, D7=D10=D11 and D8=D9=D12. If compared with distances from the aforementioned embodiment, distance D7 is slightly less than the distance D1, the distance D1 is slightly less than the distance D2, and the distance D2 is equal to the distance D8.

It should be noted that in contrast to the aforementioned approach of first conducting a first ion implantation process 36 on the HV regions 102, 106, rotating the substrate 12 180 degrees, and then conducting another ion implantation process 104 on the LV region 104 when the substrate 12 kept still or remains stopped as shown in FIGS. 3-4, this embodiment only conducts a single ion implantation process 84 at a tilt angle while the substrate 12 is rotating to form the LDDs 88, 90, 92, 94, 96, 98 adjacent to two sides of the gate structures 22, 24, 26. In other words, by using the shielding of the patterned mask 82, the tilt angle ion implantation process, and rotation of the substrate, 12, the present embodiment is able to form asymmetric LDDs 88, 90, 92, 94, 96, 98 in a single step.

It should further be noted that even though sidewalls of the patterned mask 82 shown in FIG. 7 may seem to be aligned with sidewalls of the gate structures 22, 24, 26, during actual operation small gaps or spacing are in fact present between the patterned mask 82 and the gate structures 22, 24, 26 so that dopants implanted during the ion implantation process 84 could pass through the aforementioned gaps and enter into the substrate 12 adjacent to two sides of the gate structures 22, 24, 26 for forming the LDDs 88, 90, 92, 94, 96, 98. Since the gap allowing the dopants to pass through and enter into the substrate 12 in this embodiment is substantially smaller than the ones from the aforementioned embodiment, the distance or width such as D7, D10, D11 of the LDDs formed immediately adjacent to the patterned mask 82 in this embodiment is also significantly smaller than the distance such as D1 of the LDD from previous embodiment.

Next, as shown in FIG. 8, process conducted in FIG. 5 could be followed by first removing the patterned mask 82, forming another spacer such as main spacer 54 adjacent to the offset spacers 32 on the HV regions 102, 106 and LV region 104, performing an ion implantation process 116 to implant n-type or p-type dopants into the substrate 12 adjacent to two sides of the main spacers 54 for forming source/drain regions 120, 122, 124, 126, and then selectively forming epitaxial layers (not shown) and/or silicides (not shown) adjacent to the main spacers 54. In contrast to the ion implantation process 84 conducted for forming the LDDs 88, 90, 92, 94, 96, 98 being a tilt angle ion implantation process, the ion implantation process 116 conducted to form the source/drain regions 120, 122, 124, 126 is a right angle ion implantation process. Hence the source/drain regions 120, 122, 124, 126 adjacent to two sides of the gate structures 22, 24, 26 are symmetric structures, in which the source/drain regions 120, 124 are preferably drain regions while the source/drain regions 122, 126 are source regions. Next, process conducted in FIG. 6 could be carried out to form an ILD layer on the gate structures 22, 24, 26, and then a RMG process could be conducted to transform the gate structures 22, 24, 26 into metal gates, and details of which are not explained herein for the sake of brevity.

Referring to FIGS. 8-9, in which the left portion of FIG. 9 illustrates distribution of dopant concentrations of FIGS. 6 and 8 extending along X-direction of the substrate and right portion of FIG. 9 illustrates distribution of dopant concentrations of FIGS. 6 and 8 extending along Y-direction of the substrate. As shown on the left portion of FIG. 9, in contrast to the lowest or valley points of the LDD concentration from FIG. 6 embodiment being closer to the center or middle portion of the gate structure 22, the two valley points of the LDD concentration from FIG. 8 embodiment are slightly asymmetrical and shifted to the left toward the offset spacer 32 and main spacer 54. As shown on the right portion of FIG. 9, in contrast to the maximum concentration of the LDD in FIG. 6 embodiment is shifted toward the bottom surface of the second semiconductor layer 18 in the substrate 12, the maximum concentration of the LDD in FIG. 8 embodiment is closer to the top surface of the second semiconductor layer 18.

Overall, the present invention discloses an improved RF device or more specifically power amplifier transistor and fabrication method thereof. In the embodiment shown in FIGS. 1-6, the present invention first conducts a first tilt angle ion implantation to form LDDs on one of the HV regions or LV regions, rotates the substrate or wafer 180 degrees, and then conducts a second tilt angle ion implantation process while the substrate or wafer is in still condition to form LDDs. Since the two tilt angle ion implantation processes are conducted before and after the substrate is rotated 180 degrees, not only the LDDs formed on the HV regions alone are asymmetric structures and the LDDs formed on the LV region alone are asymmetric structures, the overall LDDs on the HV regions and adjacent LDDs on the LV region are also mirror images structures to each other. Preferably, the asymmetric design of the LDD structures is able to improve overall robustness of the device.

In contrast to conducting two tilt angle ion implantation processes before and after rotating the substrate 180 degrees while the substrate is kept still for forming LDDs in FIGS. 1-6, the embodiment disclosed in FIGS. 7-8 could be employed to only conduct a single tilt angle ion implantation process for forming LDDs in the substrate adjacent to two sides of the gate structures on the HV region and LV region at the same time. By using this approach to fabricate power amplifiers, it would be desirable to simplify the overall fabrication process and provide greater asymmetry so that cut-off frequency (FT) and maximum oscillation frequency (Fmax) could be improved significantly while high breakdown voltage (BV) and low leakage is maintained, thereby further increasing robustness of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a substrate having a high-voltage (HV) region and a low-voltage (LV) region;
forming a first gate structure on the HV region and a second gate structure on the LV region;
forming a first lightly doped drain (LDD) adjacent to one side of the first gate structure and a second LDD adjacent to another side of the first gate structure, wherein the first LDD and the second LDD are asymmetrical; and
forming a third lightly doped drain (LDD) adjacent to one side of the second gate structure and a fourth LDD adjacent to another side of the second gate structure, wherein the third LDD and the fourth LDD are asymmetrical and the second LDD and the third LDD are symmetrical.

2. The method of claim 1, further comprising:
forming a first spacer adjacent to the first gate structure and a second spacer adjacent to the second gate structure;
performing a first ion implantation process to form the first LDD and the second LDD
performing a second ion implantation process to form the third LDD and the fourth LDD;
forming a third spacer adjacent to the first spacer and a fourth spacer adjacent to the second spacer; and
forming a first source/drain (S/D) region on one side of the first gate structure, a second S/D region between the first gate structure and the second gate structure, and a third S/D on another side of the second gate structure.

3. The method of claim 2, wherein the first ion implantation process comprises a tilt angle implantation process.

4. The method of claim 2, wherein the second ion implantation process comprises a tilt angle implantation process.

5. The method of claim 2, further comprising performing the first ion implantation process and the second ion implantation process at opposite direction.

6. The method of claim 2, further comprising performing the first ion implantation process and the second ion implantation process at same angle.

7. The method of claim 2, further comprising performing the first ion implantation process and the second ion implantation process at same concentration.

8. The method of claim 1, wherein the substrate comprises a silicon-on-insulator (SOI) substrate.

9. A semiconductor device, comprising:
a substrate having a high-voltage (HV) region and a low-voltage (LV) region;
a first gate structure on the HV region and a second gate structure on the LV region;
a first lightly doped drain (LDD) adjacent to one side of the first gate structure and a second LDD adjacent to another side of the first gate structure, wherein the first LDD and the second LDD are asymmetrical; and
a third lightly doped drain (LDD) adjacent to one side of the second gate structure and a fourth LDD adjacent to another side of the second gate structure, wherein the third LDD and the fourth LDD are asymmetrical and the second LDD and the third LDD are symmetrical.

10. The semiconductor device of claim 9, further comprising:
a first source/drain (S/D) region on one side of the first gate structure;
a second S/D region between the first gate structure and the second gate structure; and
a third S/D on another side of the second gate structure.

11. The semiconductor device of claim 10, wherein the first S/D region, the second S/D region, and the third S/D region are symmetrical.

12. The semiconductor device of claim 9, wherein the first LDD and the second LDD comprise same concentration.

13. The semiconductor device of claim 9, wherein the third LDD and the fourth LDD comprise same concentration.

14. The semiconductor device of claim 9, wherein the substrate comprises a silicon-on-insulator (SOI) substrate.
